(19) United States
(12) Patent Application Publication
(10) Pub. No.: US 2007/0148491 A1
(43) Pub. Date: Jun. 28, 2007

(54) Conjugated polymer end-capped with phosphorescent organometallic complex, light-emitting element and light-emitting device

(75) Inventors: Steve Lien-Chung Hsu, Tainan County (TW); Po-I Lee, Tainan County (TW)

Correspondence Address: BIRCH STEWART KOLASCH & BIRCH, PO BOX 747, FALLS CHURCH, VA, 22040-0747, US

(73) Assignee: National Cheng Kung University Chi Mei Optoelectronics Corp.

(21) Appl. No.: 11/313,938

(22) Filed: Dec. 22, 2005

(51) Int. Cl. H01L 51/54; C09K 11/06

(52) U.S. Cl. 428/690; 428/917; 313/504; 313/506; 257/40; 257/E51.032; 257/E51.044

(57) ABSTRACT

Disclosed is an electroluminescent conjugated polymer end-capped with organometallic complex. The end-capped conjugated polymer may have a partial structure represented by the following formula (I): 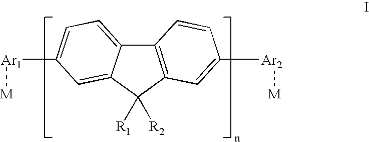
wherein M is a metal selected from the group consisting of Ir, Os, Pt, Pb, Re, and Ru; R₁ and R₂ may be the same or different and each represent a hydrogen atom or a substituent; Ar₁ and Ar₂ may be the same or different and each represent a substituted or unsubstituted heterocyclic group containing nitrogen for forming a coordination bond with M; and n is an integer of from 20 to 50. The end-capped conjugated polymers of the present invention may be used as an electroluminescent medium in a light-emitting element or a light-emitting device.

### FIELD OF THE INVENTION

This invention relates to conjugated polymers end-capped with two phosphorescent organometallic complexes and light-emitting elements that use the end-capped conjugated polymers.

### BACKGROUND OF THE INVENTION

Light-emitting elements using organic luminescent materials have been actively researched recently because of wider viewing angles and faster response time than conventional LCDs. More particularly, when using organic compounds as a luminescent material, it has been expected to realize a flat panel display, which makes use of spontaneous light and has a high response speed regardless of an angle of field. These light-emitting elements when incorporated in consumer electronic devices such as digital camera, PDA and videophones will offer several advantages such as low power consumption, high brightness, and light and thin design.

A representative example of light-emitting element is a light-emitting diode (LED) device such as organic light-emitting diodes (OLED) and polymer light-emitting diodes (PLED). Typically, the LED device has a thin film, which contains a luminescent material capable of emitting light through the charge of an electric current and is formed between an optically transparent anode and a metallic cathode. For the production of full-color LED display panel, it is necessary to have efficient red, green and blue (RGB) electroluminescent materials with proper chromaticity and sufficient luminance efficiency.

The application research of electrophosphorescent materials containing organometallic complexes in fabricating OLED devices has received much attention for their high luminance efficiency. Both singlet and triplet excitons can be fully utilized in electrophosphorescence due to the strong spin-orbital coupling effect of heavy-metal ions in phosphorescent complexes. Therefore, a maximum 100% internal quantum efficiency can be achieved theoretically.

Several researches have been reported about using organometallic complexes as the dopant in host material (e.g., conjugated polymers) to obtain an OLED device with good external quantum efficiency. The resulted devices' efficiencies are improved significantly, although there might have been a phase separation problem between the dopant and the conjugated polymer. Incorporating organometallic complexes into the conjugated polymers backbones for use as phosphorescent polymer materials has also been reported. For example, rhenium complex was connected on the main-chain of polyfluorenes (J. Phys. Chem. B 2004, 108, 13185), and iridium complex was attached on the side-chain of polyfluorenes (J. Am. Chem. Soc. 2003, 125, 636; Macromolecules 2005, 38, 4072).

However, it is quite difficult to control the molecular weight of the product in the reaction of incorporating organometallic complexes into the conjugated polymers backbones. For conjugated polymers to be used in the fabrication of LED devices, the molecular weight of polymers is an important factor. If the molecular weight is too low, it is difficult to form a good film. On the other hand, if the molecular weight is too high, the polymers are hard to dissolve in the solvent.

Therefore, there is a continuing need for electroluminescent materials that do not have the phase separation problem in the direct organometallic complexes doping approach as well as can be prepared with a high degree of control over the molecular weight.

### SUMMARY OF THE INVENTION

Therefore, it is an object of the present invention to provide an electroluminescent material that does not has the phase separation problem observed in the direct organometallic complexes doping approach as well as can be prepared with a high degree of control over the molecular weight.

To achieve the above listed and other objects, the present invention provides a conjugated polymer end-capped with two phosphorescent organometallic complexes such as Re-complex, Ru-complex, or Ir-complex. The backbone of the conjugated polymer may have a repeating unit of fluorene. The end-capped conjugated polymer of the present invention can be used as an electroluminescent material to make a light-emitting element.

Specifically, the end-capped conjugated polymer of the present invention may have a partial structure represented by the following formula (I):

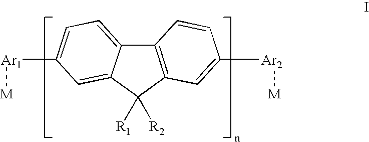

wherein:

M is a metal selected from the group consisting of Ir, Os, Pt, Pb, Re, and Ru;

R₁ and R₂ may be the same or different and each represent a hydrogen atom or a substituent;

Ar₁ and Ar₂ may be the same or different and each represent a substituted or unsubstituted heterocyclic group containing nitrogen for forming a coordination bond with M; and

n is an integer of from 20 to 50.

To achieve the above listed and other objects, the present invention further provides a light-emitting element made of the compound represented by formula (I).

In the present invention, an end-capping reagent (such as 3-bromopyridine) is used to control the molecular weight of polyfluorenes. The other purpose of end-capping is to incorporate an electrophosphorescent organic metal, such as rhenium, in the polymer through the formation of pyridine-rhenium complexes. This is a new approach to preparing electrophosphorescent polymers, which do not have the phase separation problem in the direct organic metals doping approach as well as can be prepared with a high degree of control over the molecular weight.

### BRIEF DESCRIPTION OF THE DRAWINGS

Other objects, advantages, and novel features of the invention will become more apparent from the following detailed description when taken in conjunction with the accompanying drawing:

FIG. 1 represents the UV-vis spectra of PFO-endpy and PFO-end2pyRe;

FIG. 2 represents the PL spectra of PFO-endpy and PFO-end2pyRe; and

FIG. 3 represents the EL spectra of PFO-endpy and PFO-end2pyRe.

### DETAILED DESCRIPTION OF THE PREFERRED EMBODIMENT

The present invention is generally directed to a conjugated polymer end-capped with two phosphorescent organometallic complexes such as Re-complex, Ru-complex, or Ir-complex. The backbone of the conjugated polymer may have a repeating unit of fluorene. The end-capped conjugated polymer of the present invention can be used as an electroluminescent material to make a light-emitting element that can be appropriately used in light-emitting devices such as displays (e.g., television or monitor), backlights, illumination light sources, and the like.

The end-capped conjugated polymer of the present invention has a partial structure represented by the following formula (I):

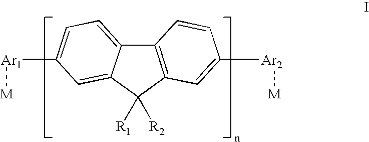

wherein n is an integer of from 20 to 50.

In the formula (I), M represents a heavy metal such as Ir, Os, Pt, Pb, Re, or Ru.

R₁ and R₂ in the formula (I) may be the same or different and each represent a hydrogen atom or a substituent preferably alkyl having from 6 to 12 carbon atoms.

Ar₁ and Ar₂ in the formula (I) may be the same or different and each represent a substituted or unsubstituted heterocyclic group containing nitrogen for forming a coordination bond with M. The nitrogen-containing group may be exemplified by substituted or unsubstituted pyridine, substituted or unsubstituted dipyridine, substituted or unsubstituted terpyridine, substituted or unsubstituted phenanthroline, dimethyldipyridine, substituted or unsubstituted phenanthroline, and substituted or unsubstituted biquinoline

Note that other ligands (not shown) of the phosphorescent organometallic complexes in the formula (I) are not particularly limited. Suitable ligands for use in the present invention include a halogen ligand, a nitrogen-containing heterocyclic ligand, a diketone ligand (e.g., acetylacetone) and a carbon monoxide ligand. In the organometallic complexes, one kind or two or more kinds of the ligands maybe used. The number of the kinds of ligands in the transition metal complex is preferably one or two.

Examples of the end-capped conjugated polymers to be used in the invention will be given below, but the present invention should not be construed as being limited thereto.

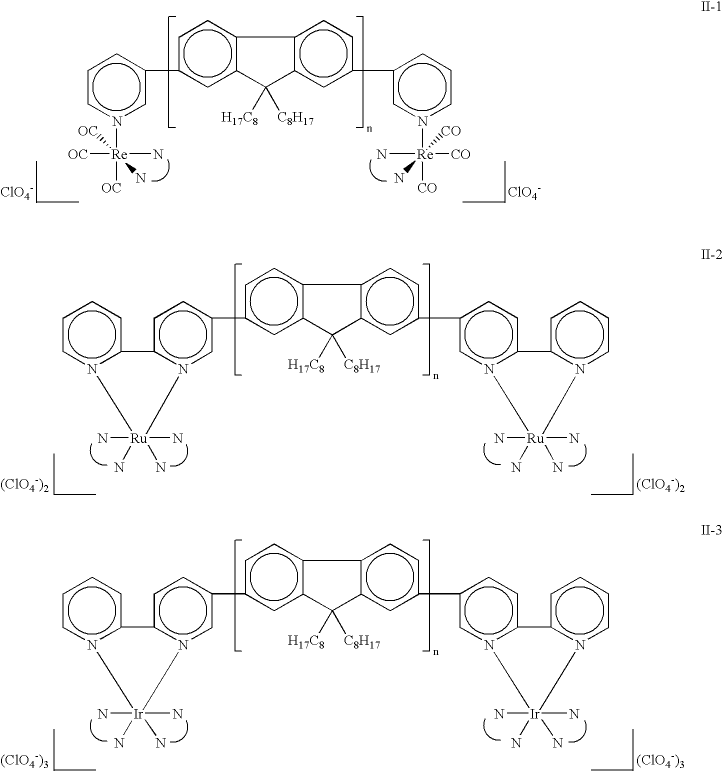

In the formulae described above, 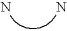
represents a dipyridine.

The phosphorescent end-capped conjugated polymers of the present invention can be used as an electroluminescent medium in a light-emitting element. The light-emitting element of the invention may comprise a light-emitting layer formed from the electroluminescent medium, or a plurality of organic compound layers including the light-emitting layer disposed between a pair of electrodes comprising an anode and a cathode. Moreover, it is possible to provide an element wherein the end-capped conjugated polymer of the invention is formed as an electroluminescent layer sandwiched between an electron transporting layer and a hole transporting layer. The light-emitting element of the invention is not specifically limited in its system, driving method and form of utilization so far as it comprises the compound of the invention. A representative application of light-emitting element is a light-emitting diode (LED) device such as organic light-emitting diodes (OLED) and polymer light-emitting diodes (PLED).

The structure of LED devices can be divided into two types: bottom emission and top emission. The bottom emission device has an anode made of a transparent electrode such as indium tin oxide (ITO) electrode on a substrate, such as glass or plastic substrate, a cathode made of opaque or reflective metal with low work function, e.g., Al or Ca:Al alloy etc., and an electrolumninescent medium is disposed between the anode and the cathode, wherein light is emitted through the transparent anode. The top emission device has an anode made of opaque or reflective metal, e.g., Al/Ni or Al/TiO, on a substrate, such as glass or plastic substrate, a cathode made of metal with low work function e.g., Ca, Al, Mg:Ag alloy, ITO etc., which becomes transparent when the cathode is formed in a small thickness, and an electrolumninescent medium is disposed between the anode and the cathode, wherein light is emitted through the transparent cathode.

The bottom emission device may be manufactured in the following way. A glass substrate is used for forming the device. On the substrate, a transparent anode, a hole injection modification layer (optional), a hole transporting layer, a light-emitting layer, a hole blocking layer, an electron transporting layer, an election injection layer of potassium fluoride (optional), and a cathode are sequentially formed. Before the organic layers are deposited, the ITO glass substrate is cleaned in commercially available detergent solution and organic solvent, and treated by a UV-ozone cleaner.

### EXAMPLE 1

### Synthesis Of Pyridine Endcapped Polyfluorene (PFO-endpy)

The synthetic sequences are outlined in Scheme 1. To a 100 mL round bottom flask, Ni(COD)₂ (2 g, 7.11 mmol), 2,2-dipyridyl (1.11 g, 7.11 mmol) and 1,5-cyclooctadiene (0.768 g, 7.11 mmol) were dissolved in 10 mL of DMF under a nitrogen atmosphere. The solution was heated to 80° C. for half an hour to form a purple complex. 2,7-Dibromo-9,9-dioctylfluorene (1.64 g, 3 mmol) and 3-bromopyridine (0.1 g, 0.6 mmol) in a mixture of toluene (30 mL) and DMF (5 mL) were added to the solution, and heated at 80° C. for another 3 days. After being cooled to room temperature, the reaction mixture was poured into a mixture of 200 mL of HCl, 200 mL of acetone and 200 mL of methanol, which was stirred for 2 h. The solid was filtered, and redissolved in chloroform. Then it was precipitated in a large amount of methanol. The pale yellow solid was dried in a vacuum oven at 60° C. for overnight to give 0.9 g of product (74% yield). ¹H-NMR (600 MHz, CDCl₃, ppm): 9.09(s, ArH), 8.68 (s, ArH), 7.99 (s, ArH), 7.93 (s, ArH), 7.83 (m, ArH),7.68 (m, ArH),2.12(t, 4H), 1.14 (m, 24H), 0.82(t, 6H). GPC (THF): Mn=7073 g/mol, Mw=13770 g/mol, PDI=1.95.

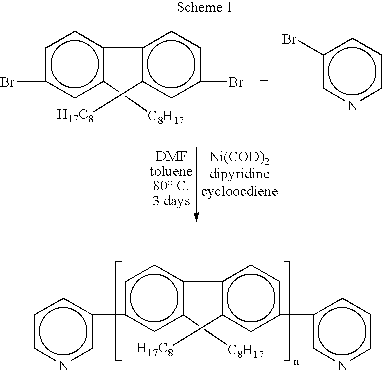

### EXAMPLE 2

### Synthesis of Exemplary Compound I

The synthesis of polyfluorene end-capped with two Re— complexes (PFO-end2pyRe) (Exemplary Compound I) is outlined in Scheme 2. Under a nitrogen atmosphere, 50 mg of PFO-endpy was dissolved in 50 mL of toluene in a 100 mL round bottom flask, kept under dark. 2,2-Bipyridyl(tricarbonyl)rhenium(I) chloride (14 mg, 0.03 mmol) and silver perchlorate (10 mg, 0.05 mmol) were added consecutively to the reaction mixture, and the resulting solution was refluxed overnight. After being cooled to room temperature, the solution was filtered to get rid of AgCl. After evaporating the solvent, the polymer solid was redissolved in chloroform, and then precipitated in a large amount of methanol. The polymer power was dried in vacuum at 60° C. overnight. The weight average molecular weight is 13,770 g/mol, and the polydispersity is 1.95. ¹H-NMR (600 MHz, CDCl₃, ppm): 9.12(s, ArH),8.74(d, ArH), 8.14(s, ArH),7.93(d, ArH),7.83(m, ArH),7.68 (m, ArH), 7.55(d, ArH), 2.12(t, 4H), 1.14(m, 24H), 0.82(t, 6H). ¹H-NMR data demonstrate that the content of pyridine unit in copolymer is 11.4 mol-%.

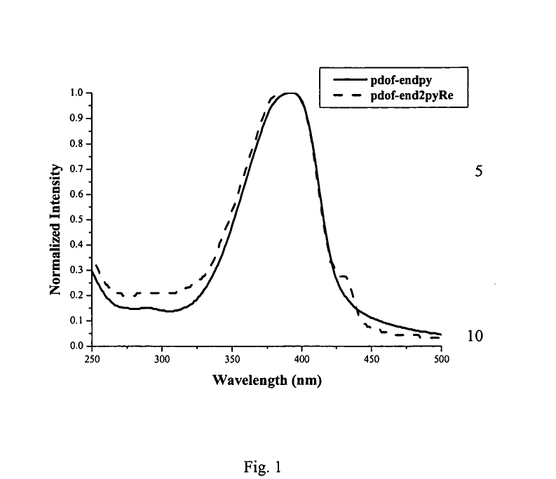

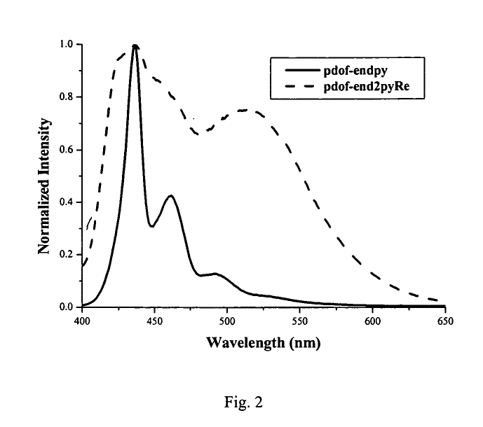

The UV-vis spectra of PFO-endpy and PFO-end2pyRe are shown in FIG. 1. An intense absorption band at 380 nm is due to the π→ π* transitions of polyfluorene, and a low intensity absorption shoulder at 430 nm is due to the metal-to-ligand charge-transfer (MLCT) transitions. As shown in FIG. 2, the PL spectrum of PFO-end2pyRe in the solid state is different from PFO-endpy with another peak at 515 nm. The peak is attributed to the phosphorescence of the Re-dipyridine complex, and indicates considerable energy transfer from the excited polyfluorene to Re-dipyridine.

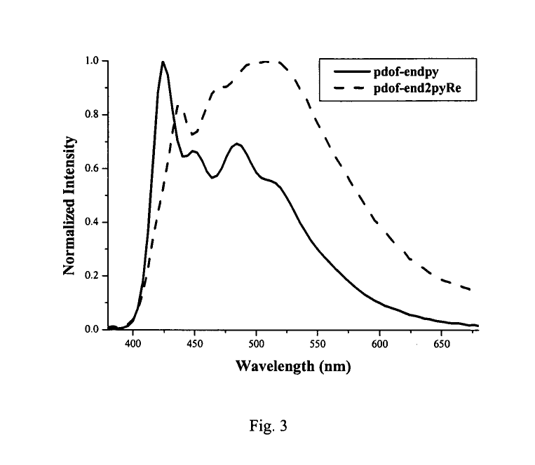

FIG. 3 shows the EL spectra of the PFO-endpy and PFO-end2pyRe. The structure of the EL device was ITO/PEDOT:PSS/emission layer/Ca—Al. The highest peak is at 516 nm, with a shoulder at 424 nm. The 516 nm peak is also observed in the PL spectrum, and is attributed to the phosphorescence of the Re-complex. Under photoexcitation, the triplet excited states are created on the main chain, and subsequently transferred to the metal-organic complex. In contrast, the charges are trapped easily on the Re complex when electrons and holes inject from electrodes, recombinating in this location. The EL spectra also show that the blue emission of PFO-endpy was changed to green when it became PFO-end2pyRe, and the emission peak became broader.

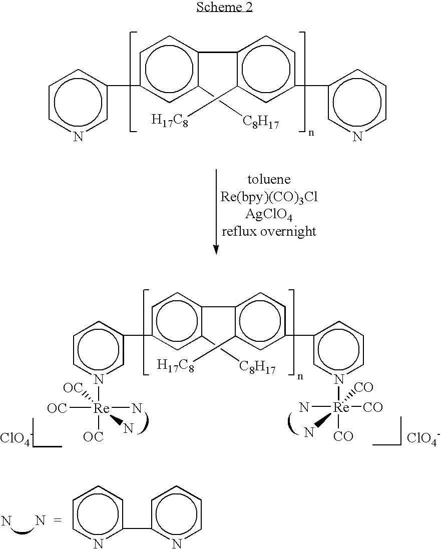

### EXAMPLE OF LIGHT-EMITTING ELEMENT

### ITO/PEDOT:PSS/emission layer/Ca—Al

Patterned indium tin oxide (ITO) glasses were cleaned with acetone, 2-propanol and deionized water in an ultrasonic bath. A thin hole injection layer of polystyrene sulfonic acid doped polyethylenedioxythiophene [PEDOT: PSS] was spin-coated on the ITO. On top of it, an electroluminescent medium was formed by spin-coating from a solution including PFO-end2pyRe (Exemplary Compound I) dissolved in chloroform. Finally, the cathode Ca—Al was formed by thermo-evaporation under a vacuum of 10⁻⁵ torr.

In the present invention, an end-capping reagent (such as 3-bromopyridine) is used to control the molecular weight of polyfluorenes. The other purpose of end-capping is to incorporate an electrophosphorescent organic metal, rhenium, in the polymer through the formation of pyridine-rhenium complexes. This is a new approach to preparing electrophosphorescent polymers, which do not have the phase separation problem in the direct organic metals doping approach as well as can be prepared with a high degree of control over the molecular weight.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. An electroluminescent material comprising a conjugated polymer end-capped with two phosphorescent organometallic complexes.

2. The electroluminescent material according to claim 1, wherein the organometallic complex is a Re-complex, Ru-complex, or Ir-complex.

3. The electroluminescent material according to claim 1, wherein the backbone of the conjugated polymer comprises a repeating unit of fluorene.

4. The electroluminescent material according to claim 1, wherein the end-capped conjugated polymer having a partial structure represented by the following formula (I): 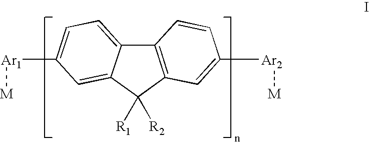
wherein:
M is a metal selected from the group consisting of Ir, Os, Pt, Pb, Re, and Ru;
R₁ and R₂ may be the same or different and each represent a hydrogen atom or a substituent;
Ar₁ and Ar₂ may be the same or different and each represent a substituted or unsubstituted heterocyclic group containing nitrogen for forming a coordination bond with M; and
n is an integer of from 20 to 50.

5. The electroluminescent material according to claim 4, wherein Ar₁ and Ar₂ are independently selected from the group consisting of substituted or unsubstituted pyridine, substituted or unsubstituted dipyridine, substituted or unsubstituted terpyridine, substituted or unsubstituted phenanthroline, dimethyldipyridine, substituted or unsubstituted phenanthroline, and substituted or unsubstituted biquinoline.

6. The electroluminescent material according to claim 4, wherein R₁ and R₂ independently represent an alkyl group of from 6 to 12 carbon atoms.

7. The electroluminescent material according to claim 1, wherein the end-capped conjugated polymer is a compound represented by the following structural formula II-1, II-2, or II-3: 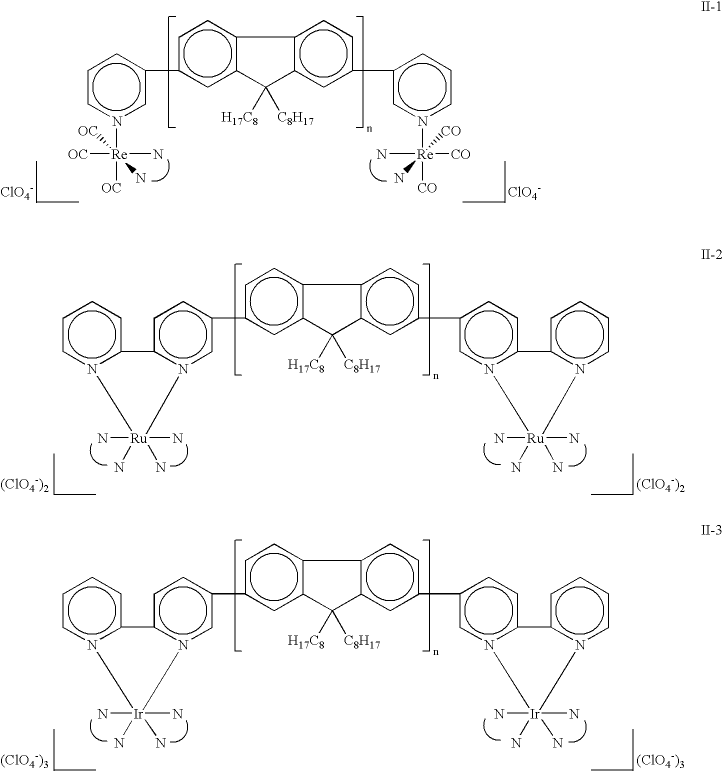
wherein 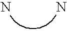
represents a dipyridine.

8. A light-emitting element, comprising:
an anode and a cathode; and
an electroluminescent medium disposed between the anode and the cathode;
wherein the electroluminescent medium comprises a conjugated polymer end-capped with two phosphorescent organometallic complexes.

9. The light-emitting element according to claim 8, wherein the organometallic complex is a Re-complex, Ru-complex, or Ir-complex.

10. The light-emitting element according to claim 8, wherein the backbone of the conjugated polymer comprises a repeating unit of fluorene.

11. The light-emitting element according to claim 8, wherein the end-capped conjugated polymer having a partial structure represented by the following formula (I): 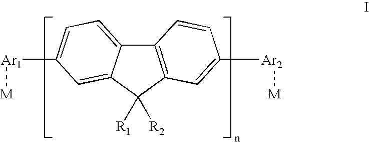
wherein:
M is a metal selected from the group consisting of Ir, Os, Pt, Pb, Re, and Ru;
R₁ and R₂ may be the same or different and each represent a hydrogen atom or a substituent;
Ar₁ and Ar₂ may be the same or different and each represent a substituted or unsubstituted heterocyclic group containing nitrogen for forming a coordination bond with M; and
n is an integer of from 20 to 50.

12. The light-emitting element according to claim 11, wherein Ar₁ and Ar₂ are independently selected from the group consisting of substituted or unsubstituted pyridine, substituted or unsubstituted dipyridine, substituted or unsubstituted terpyridine, substituted or unsubstituted phenanthroline, dimethyldipyridine, substituted or unsubstituted phenanthroline, and substituted or unsubstituted biquinoline.

13. The light-emitting element according to claim 11, wherein R₁ and R₂ independently represent an alkyl group of from 6 to 12 carbon atoms.

14. The light-emitting element according to claim 8, wherein the end-capped conjugated polymer is a compound represented by the following structural formula II-1, II-2, or II-3: 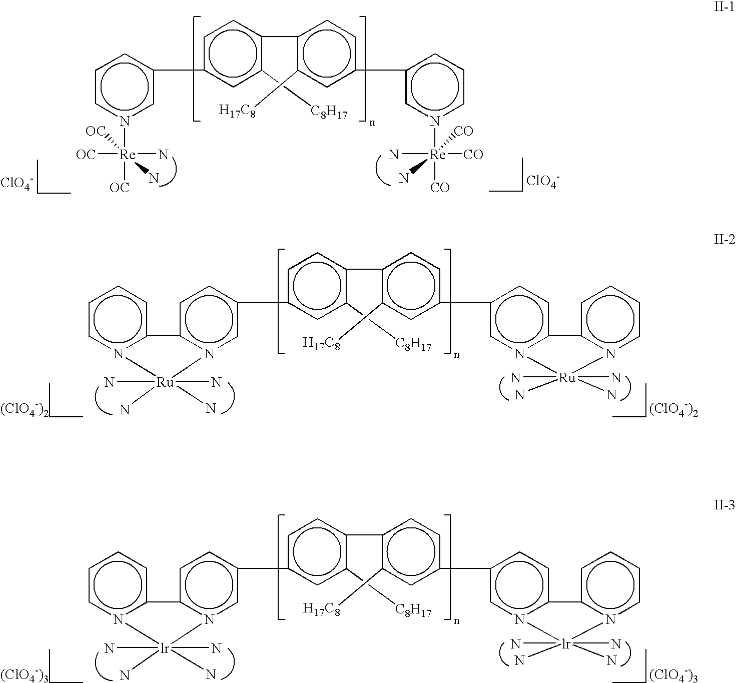
wherein 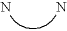
represents a dipyridine.

15. A light-emitting device, comprising:
a substrate;
a first electrode on the substrate;
a second electrode; and
an electroluminescent medium disposed between the first electrode and the second electrode;
wherein the electroluminescent medium comprises a conjugated polymer end-capped with two phosphorescent organometallic complexes.

16. The light-emitting device according to claim 15, wherein the organometallic complex is a Re-complex, Ru-complex, or Ir-complex.

17. The light-emitting device according to claim 15, wherein the backbone of the conjugated polymer comprises a repeating unit of fluorene.

18. The light-emitting device according to claim 15, wherein the end-capped conjugated polymer having a partial structure represented by the following formula (I): 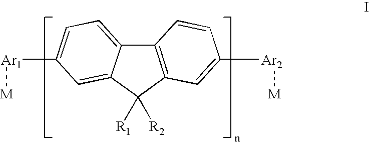
wherein:
M is a metal selected from the group consisting of Ir, Os, Pt, Pb, Re, and Ru;
R₁ and R₂ may be the same or different and each represent a hydrogen atom or a substituent;
Ar₁ and Ar₂ may be the same or different and each represent a substituted or unsubstituted heterocyclic group containing nitrogen for forming a coordination bond with M; and
n is an integer of from 20 to 50.

19. The light-emitting device according to claim 15, wherein Ar₁ and Ar₂ are independently selected from the group consisting of substituted or unsubstituted pyridine, substituted or unsubstituted dipyridine, substituted or unsubstituted terpyridine, substituted or unsubstituted phenanthroline, dimethyldipyridine, substituted or unsubstituted phenanthroline, and substituted or unsubstituted biquinoline.

20. The light-emitting device according to claim 15, wherein the end-capped conjugated polymer is a compound represented by the following structural formula II-1, II-2, or II-3: 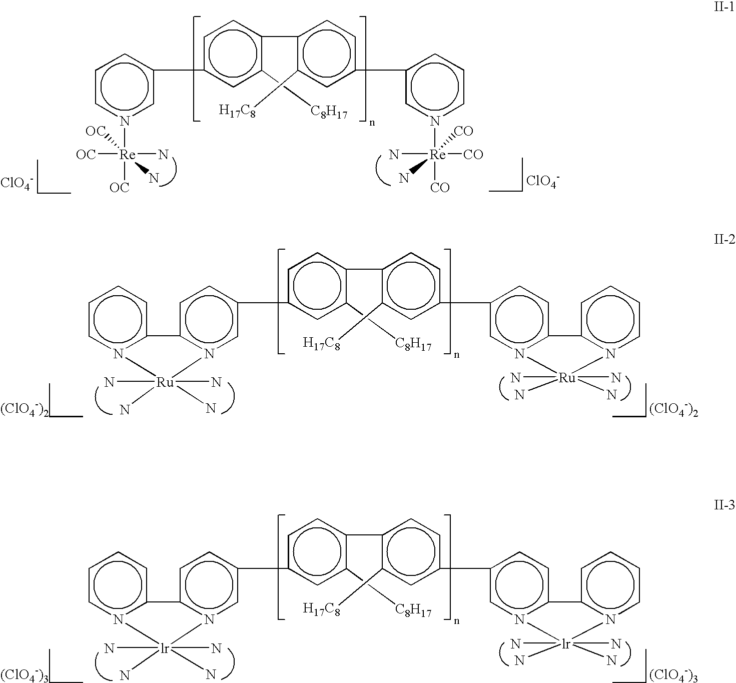
wherein 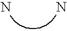
represents a dipyridine.
